(19) United States
(12) Patent Application Publication
(10) Pub. No.: US 2009/0266711 A1
(43) Pub. Date: Oct. 29, 2009

(54) SUBSTRATE PROCESSING APPARATUS

(75) Inventors: Kiyotaka ISHIBASHI, Amagasaki City (JP); Toshihisa NOZAWA, Amagasaki City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/407,959

(22) Filed: Mar. 20, 2009

(30) Foreign Application Priority Data
Apr. 28, 2008 (JP) 2008-116973

(51) Int. Cl. C23C 14/34

(52) U.S. Cl. 204/298.07

(57) ABSTRACT

The substrate processing apparatus includes: at least one processing chamber in which a semiconductor wafer is processed; a transfer chamber disposed adjacent to the at least one processing chamber; a vacuum pump for depressurizing an inside of the transfer chamber; a transfer device for carrying the semiconductor wafer between the transfer chamber and the at least one processing chamber; and a foreign substance removing unit for removing foreign substances adhered to the transfer device in the transfer chamber.

### CROSS-REFERENCE TO RELATED PATENT APPLICATION

This application claims the benefit of Japanese Patent Application No. 2008-0116973, filed on Apr. 28, 2008, in the Japan Patent Office, the disclosure of which is incorporated herein in its entirety by reference.

### BACKGROUND OF THE INVENTION

1. Field of the Invention

The present invention relates to a substrate processing apparatus.

2. Description of the Related Art

Substrate processing apparatuses remove foreign substances adhered to a surface of a carrier arm. Examples of such apparatuses are disclosed in Japanese Patent Laid-open Publication Nos. H11-40642, (referred to as cited reference 1), and H8-327959 (referred to as cited reference 2).

The substrate processing apparatus disclosed in the cited reference 1 includes an indexer having a cassette in which a plurality of substrates are received, a heat treatment unit for heat-treating a substrate, a spin coater for coating the substrate with photoresist while rotating the substrate, a spin developer for developing the substrate after exposure of the substrate, a carrier arm for carrying the substrate in a loop between processing units, and an ultraviolet emitting unit for cleaning the carrier arm by emitting ultraviolet light toward the carrier arm (see Paragraph No. 0024 and FIG. 1).

The sputter apparatus disclosed in the cited reference 2 includes a cassette loader for receiving a semiconductor wafer, a vacuum chamber including a plurality of sputter chambers, a carrier arm for carrying the semiconductor wafer between the cassette loader and the vacuum chamber, and a surface processing unit disposed in a path in which the semiconductor wafer is carried (see Paragraph No. 0083 and FIG. 12).

In case of the substrate processing apparatus disclosed in the cited reference 1, since the substrate processing apparatus employs the ultraviolet emitting unit that is used only to clean the carrier arm, the area occupied by the substrate processing apparatus is increased. Also, since the substrate cannot be carried during the cleaning of the carrier arm, the throughput of the substrate processing apparatus is reduced.

In case of the sputter apparatus disclosed in the cited reference 2, since the surface processing unit disposed in the path in which the semiconductor wafer is carried dry-cleans the carrier arm by generating a gas discharge at or around an atmospheric pressure, the surface processing unit tends to be large. Also, foreign particles may be generated during the gas discharge.

### SUMMARY OF THE INVENTION

The present invention provides a substrate processing apparatus for removing foreign substances from a surface of a transfer arm disposed in a transfer chamber, the apparatus having a simple structure and being adapted to efficiently remove foreign substances without increasing the occupied area and to maintain a high degree of freedom in carrying a substrate without reducing throughput.

According to an aspect of the present invention, there is provided a substrate processing apparatus comprising: at least one processing chamber in which a substrate is processed; a transfer chamber disposed adjacent to the at least one processing chamber; a depressurizing unit for depressurizing an inside of the transfer chamber; a transfer device for carrying the substrate between the transfer chamber and the at least one processing chamber; and a foreign substance removing unit for removing foreign substances adhered to the transfer device in the transfer chamber.

The substrate processing apparatus removes the foreign substances adhered to the transfer device in the transfer chamber that is in a depressurized state such as a vacuum state. Accordingly, the foreign substances are removed in the transfer chamber without increasing the occupied area while maintaining high throughput. Herein, the depressurized state referred to in this disclosure includes a state in which ozone gas is filled in the transfer chamber.

The foreign substance removing unit may comprise a light emitting unit for emitting light to the transfer device so that the foreign substances are transformed from a solid phase to a gas phase due to heat energy of the light. Accordingly, the foreign substances are removed from a surface of the transfer device.

Preferably, the foreign substance removing unit may remove the foreign substances in the transfer chamber by using ozone gas. Accordingly, the efficiency in removing the foreign substances is improved. The ozone gas may be generated in the transfer chamber or may be supplied into the transfer chamber after being generated outside the transfer chamber.

As an aspect of the present invention, the foreign substance removing unit may comprise an ozone gas supply unit for supplying ozone gas into the transfer chamber. Alternatively, the foreign substance removing unit may comprise an ozone gas injecting unit for injecting ozone gas to the transfer device. Accordingly, the ozone gas may be filled in the transfer chamber or may be selectively injected to the transfer device.

Preferably, a surface of the transfer device may be covered with a titanium oxide layer. Accordingly, the efficiency in removing the foreign substances is further improved.

Preferably, the transfer chamber may have a transmissive window through which light is transmitted. The light emitting unit may emit light to the transfer device through the transmissive window from the outside of the transfer chamber. Accordingly, the foreign substances in the gas phase which are removed from the transfer device are prevented from being adhered to the light emitting unit.

Preferably, the transfer device may have a plurality of protrusions formed on a top surface thereof and supporting the substrate. The foreign substance removing unit may selectively remove foreign substances adhered to the plurality of protrusions. Although a process for removing foreign substances may be performed on the entire transfer device, the effect of the present invention can also be achieved when the process is performed only on the protrusions that directly contact the substrate.

Preferably, the transfer chamber may comprise a suction device for forcibly discharging foreign substances separated from the transfer device. Accordingly, the foreign substances in the gas phase floating in the transfer chamber are prevented from being adhered to the substrate.

According to another aspect of the present invention, there is provided a substrate processing apparatus comprising: at least one processing chamber in which a substrate is processed; a transfer chamber disposed adjacent to the at least one processing chamber; a depressurizing unit for depressurizing an inside of the transfer chamber; a load lock chamber disposed adjacent to the transfer chamber; a first transfer device disposed in the transfer chamber and carrying the substrate to the at least one processing chamber and the load lock chamber under a depressurized atmosphere; a loader unit disposed adjacent to the load lock chamber and comprising a cassette for receiving the substrate and a second transfer device for carrying the substrate between the load lock chamber and the cassette; and a foreign substance removing unit for removing foreign substances adhered to the first transfer device in the transfer chamber.

Since the first transfer device and the second transfer device operate independently in the substrate processing apparatus, each of the first transfer device and the second transfer device can operate without being limited by the working rate of the other device. Hence, the substrate processing apparatus has a high degree of freedom in carrying or processing a substrate. Also, since the foreign substances adhered to the first transfer device are removed, foreign substances are prevented from being introduced into the cassette in which the substrate is received.

### BRIEF DESCRIPTION OF THE DRAWINGS

The above and other features and advantages of the present invention will become more apparent by describing in detail exemplary embodiments thereof with reference to the adhered drawings in which:

FIG. 1 is a schematic view of a substrate processing apparatus according to an embodiment of the present invention;

FIG. 2 is a cross-sectional view illustrating the internal structure of a processing chamber;

FIG. 3 is a cross-sectional view illustrating the structure of a transfer chamber and a foreign substance removing unit; and

FIG. 4 is a cross-sectional view illustrating an alternative embodiment which is modified from the one shown in FIG. 3.

### DETAILED DESCRIPTION OF THE INVENTION

The present invention will now be described more fully with reference to the accompanying drawings, in which exemplary embodiments of the invention are shown.

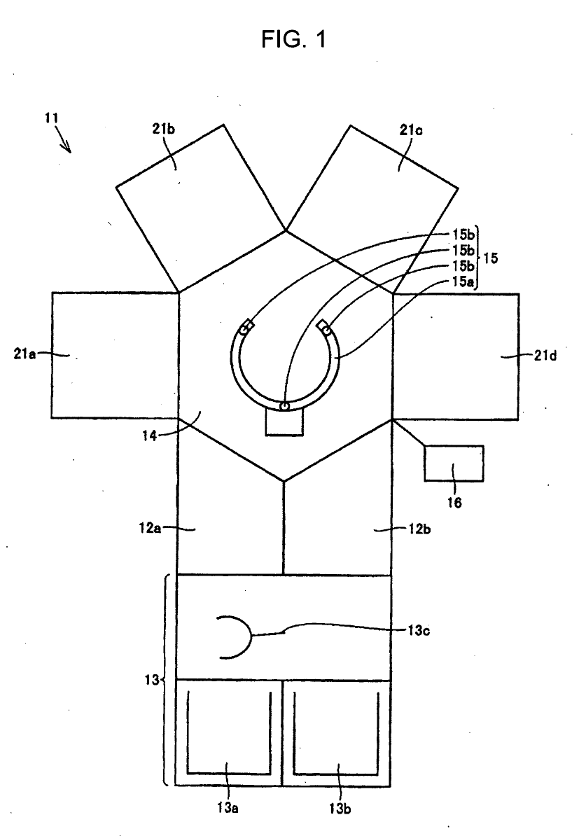

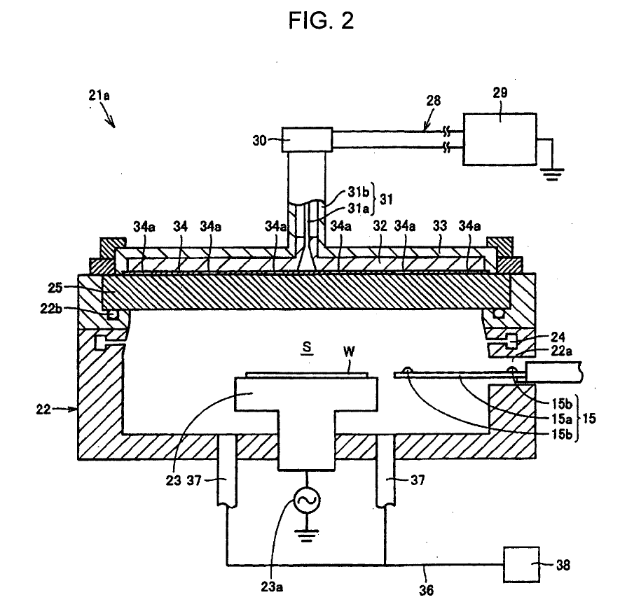

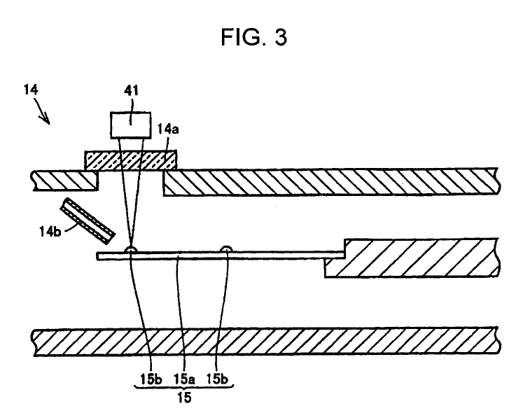

A substrate processing apparatus 11 according to an embodiment of the present invention will now be explained with reference to FIGS. 1 through 3. FIG. 1 is a schematic view of a substrate processing apparatus 11 according to an embodiment of the present invention. FIG. 2 is a cross-sectional view illustrating the internal structure of a processing chamber 21a. FIG. 3 is a cross-sectional view illustrating the structure of a transfer chamber and a foreign substance removing unit.

Referring to FIG. 1, the substrate processing apparatus 11 is a so-called cluster tool structure mainly including: load lock chambers 12a and 12b through which a semiconductor wafer W, which is a substrate to be processed, is carried into and out of a transfer chamber 14 that is in a depressurized state; a loader unit 13 for carrying the semiconductor wafer W into and out of the load lock chambers 12a and 12b; at least one processing chamber 21 (e.g., four processing chambers 21a, 21b, 21c and 21d in this embodiment) in which the semiconductor wafer W is respectively processed; the transfer chamber 14 disposed adjacent the load lock chambers 12a and 12b and the processing chamber 21; a transfer device 15, which is a first transfer device, for carrying the semiconductor wafer W; a vacuum pump 16 for depressurizing an inside of the transfer chamber 14 and the load lock chambers 12a and 12b; and a foreign substance removing unit for removing foreign substances adhered to the transfer device 15 in the transfer chamber 14.

The loader unit 13 includes wafer cassettes 13a and 13b in which the semiconductor wafer W is received and an arm 13c, which is a second transfer device, for carrying the semiconductor wafer W between the wafer cassettes 13a and 13b and the load lock chambers 12a and 12b. The transfer device 15 includes a transfer arm 15a and a plurality of protrusions 15b formed on the transfer arm 15a and supporting the semiconductor wafer W, and carries the semiconductor wafer W in the substrate processing apparatus 11.

Since the transfer device 15, which carries the semiconductor wafer W between the load locks chambers 12a and 12b, the transfer chamber 14, and the processing chamber 21, and the arm 13c, which carries the semiconductor wafer W between the wafer cassettes 13a and 13b and the load lock chambers 12a and 12b, operate independently, each of the transfer device 15 and the arm 13c can operate without being limited by the working rate of the other device. Hence, the substrate processing apparatus can have a high degree of freedom in carrying or processing a substrate.

A layer, e.g., a CFx layer, containing at least carbon and fluorine is formed on a surface of the semiconductor wafer W during processing in at least the processing chamber 21a among the plurality of processing chambers 21. CFx refers to a compound containing one or more elements represented by formula CyFz, where y and z are integers and may have various combinations.

Referring to FIG. 2, the internal structure of a processing chamber 21a is described. The processing chamber 21a mainly includes a processing container 22 and a dielectric body 25, which form a processing space S, a microwave supply device 28, and an exhaust device 38.

The processing container 22 is a cylindrical body with an open top and a closed bottom. The processing container 22 includes an opening portion 22a formed in a side wall and allowing the semiconductor wafer W to enter therethrough, a susceptor 23 formed in the processing container 22 and supporting the semiconductor wafer W, and a gas introducing portion 24 through which a processing gas is introduced therein. The opening portion 22a has a door (not shown). When the door opens, the semiconductor wafer W may enter the processing container 22, and when the door closes, the processing space S is sealed.

The susceptor 23 controls the temperature of the surface of the semiconductor wafer W and is connected to an alternating current (AC) power source 23a that generates a high frequency bias voltage. The processing gas introducing portion 24 is formed in the side wall of the processing container 22 and allows a processing gas to be supplied from a processing gas supply source (not shown) to the processing space S. The processing gas includes a gas for plasma excitation, e.g., Ar gas, and a gas for wafer processing, e.g., C₅F₈ gas.

The dielectric body 25 is a disk-shaped member formed of alumina (Al₂O₃) or quartz (SiO₂) and is disposed to close the open top of the processing container 22. A seal material 22b is applied to a contact surface between the processing container 22 and the dielectric body 25 to seal the processing space S.

The microwave supply device 28 supplies microwaves to the dielectric body 25 in order to generate plasma on a bottom surface of the dielectric body 25. The microwave supply device 28 includes a microwave source 29 generating microwaves of a predetermined frequency, a load matching device 30, a coaxial waveguide 31, a wavelength-shortening plate 32, an antenna cover 33 covering the wavelength-shortening plate 32, and a slot antenna 34.

The coaxial waveguide 31 includes an inner conductor 31a and an outer cladding 31b covering the inner conductor 31a. The inner conductor 31a has an end connected to the microwave source 29 through the load matching device 30 and the other end connected to the slot antenna 34, such that microwaves generated by the microwave source 29 are supplied to the slot antenna 34.

The slot antenna 34 is a thin copper disk which is plated with a conductive material such as Ag or Au, and is disposed on a top surface of the dielectric body 25. A plurality of long slots 34a are formed in the slot antenna 34, with the slots 34a penetrating the slot antenna 34 in a thickness direction. The microwaves generated by the microwave source 29 are radiated into the processing container 22 through the slots 34a and the dielectric body 25.

The exhaust device 38 is a vacuum pump allowing the processing gas to go out of the processing space S through exhaust pipes 36 and 37 that connect the exhaust device 38 and the processing container 22.

The operation of the substrate processing apparatus 11 will now be explained.

The semiconductor wafer W is carried into the processing chamber 21a by the transfer device 15. Specifically, the transfer device 15 extracts the semiconductor wafer W, which has not yet been completely processed, from the load lock chamber 12a. The semiconductor wafer W, which has not yet been completely processed, is carried into the processing chamber 21a through the transfer chamber 14, and is put on the susceptor 23.

The transfer device 15 is moved from the processing chamber 21a to the transfer chamber 14, and then the door of the processing chamber 21a is closed to seal the processing space S. A processing gas, such as a mixture of Ar gas and C₅F₈ gas, is supplied by the gas introducing portion 24 into the processing space S, and the remaining part of the processing gas is discharged out of the processing container 22 by the exhaust device 38. Accordingly, the processing space S is kept at a predetermined pressure.

The microwave source 29 generates microwaves, and supplies the microwaves to the dielectric body 25 through the load matching device 30, the coaxial waveguide 31, the wavelength-shortening plate 32, and the slot antenna 34 in order to generate an electric field on the bottom surface of the dielectric body 25. Accordingly, a gas for plasma excitation filled in the processing space S is ionized and turned into plasma.

When a gas for wafer processing is excited by the plasma, the gas for wafer processing is dissociated and begins to float in the processing space S. The floating gas is transformed into a solid phase on a surface of the semiconductor wafer W and forms a layer containing at least carbon and fluorine.

When the door of the processing chamber 21a is opened after such a plasma treatment ends, the semiconductor wafer W is carried out of the processing chamber 21a and then carried into the next processing chamber 21b by the transfer device 15. The above processes are performed repeatedly, and then the semiconductor wafer W, which has been completely processed, is carried into the load lock chamber 12b by the transfer device 15.

Deposits, which are produced from reactions in the inside of the processing chamber 21a, are accumulated on a surface of the transfer device 15 during the above processes. Specifically, CFx gas, which is in a gas phase, may float in the atmosphere of the processing space S after the plasma treatment and then may be transformed into a solid phase as deposits on the surface of the transfer device 15. After the plasma treatment, since the temperature of an inner wall of the processing chamber 21a is high, e.g., about 180° C., whereas the temperature of the transfer device 15 is relatively low, e.g., room temperature, deposits may tend to accumulate on the surface of the transfer device 15. Alternatively, since deposits are also accumulated on a surface of the susceptor 23, the deposits may be adhered to a rear surface of the semiconductor wafer W and also to surfaces of the transfer device 15 (the protrusions 15b).

Once the deposits which are foreign substances are accumulated on the transfer device 15, especially accumulated on the protrusions 15b of the transfer arm 15a of the transfer device 15, there is a risk that the semiconductor wafer W may slip off the transfer device 15 while being carried. Accordingly, the deposits accumulated on the transfer device 15 need to be removed by the foreign substance removing unit.

The transfer chamber 14 and the foreign substance removing unit will now be explained with reference to FIG. 3. The transfer chamber 14 includes a transmissive window 14a formed in a ceiling thereof and allowing light to be transmitted therethrough and a suction device 14b for forcibly discharging deposits separated from the transfer device 15. The transfer chamber 14 is kept in a vacuum state by the vacuum pump 16.

The foreign substance removing unit for removing the deposits accumulated on the transfer device 15 includes, in this embodiment, light emitting units 41 for emitting light to the transfer device 15. The light emitting units 41 are disposed right above the protrusions 15b of the transfer device 15 with the transmissive window 14a therebetween, and emit light that is focused on the protrusions 15b.

The light emitting units 41 emit light to the protrusions 15b when the transfer device 15 arrives at a predetermined position of the transfer chamber 14. The solid-phase deposits accumulated on the protrusions 15b may be decomposed by the heat energy of the light.

In the substrate processing apparatus 11 constructed as described above, since deposits accumulated on the protrusions 15b can be removed when the transfer device 15 does not support the semiconductor wafer W while the inside of the transfer chamber 14 is kept in a vacuum state, the substrate processing apparatus 11 can prevent the throughput of the processing chamber 21 from being reduced. Also, since deposits can be removed without using an exclusive cleaning unit, the area occupied by the substrate processing apparatus 11 does not need to be increased. Furthermore, since deposits are removed while the inside of the transfer chamber 14 is kept in a vacuum state, light emitted by the light emitting units 41 is not absorbed by gas particles, thereby improving the cleaning efficiency. Moreover, deposits do not need to be removed every time the semiconductor waver W is carried into the processing chamber 21 by the transfer device 15, but need to be removed once per a predetermined number of times, e.g., once per 1000 times.

When the deposits are removed, the transfer chamber 14 may be kept in a vacuum state, or ozone gas may be supplied into the transfer chamber 14 by an ozone gas supply unit. Specifically, ozone gas may be filled in the transfer chamber 14, or may be injected into the protrusions 15b from a nozzle 43 as described later. In this case, a chain of deposits is decomposed by light heat energy and thus CF₄ or CO₂ is generated due to a reaction with the ozone gas.

The deposits separated from the protrusions 15b, which are in a gas phase, float in the atmosphere of the transfer chamber 14. Accordingly, the suction device 14b is disposed so that it is placed around the protrusions 15b when the transfer device 15 arrives at a predetermined position, and the suction device 14b forcibly discharges the deposits, which are foreign substances in a gas phase, separated from the protrusions 15b. Therefore, the deposits in the gas phase, which float in the atmosphere of the transfer chamber 14, can be effectively prevented from being adhered again to the semiconductor wafer W.

The suction device 14b is not an essential element and may be omitted. If the suction device 14b is omitted, the foreign substances in the gas phase separated from the protrusions 15b are discharged from the transfer chamber 14 by the vacuum pump 16.

At least the surfaces of the protrusions 15b may be covered by a titanium oxide (TiO₂) layer. The titanium oxide layer may act as a photocatalyst that accelerates separation of the deposits from the protrusions 15b.

The deposits in the transfer device 15 may be removed for tens of seconds while the semiconductor wafer W is processed in the processing chamber 21 for several minutes. Accordingly, the throughput of the substrate processing apparatus 11 can be prevented from being reduced.

Although light is selectively emitted to the protrusions 15b of the transfer arm 15a in this embodiment, the present invention is not limited thereto and light may be emitted to the entire transfer arm 15a. However, since only the protrusions 15b directly contact the semiconductor wafer W, slipping of the semiconductor wafer W can be prevented by removing only the deposits accumulated on the protrusions 15b. Otherwise, slipping of the semiconductor wafer W can be prevented by removing at least deposits accumulated within a radius of tens of micrometers (μm) around the top of the protrusions 15b without removing the deposits accumulated on the entire surfaces of the protrusions 15b.

Although the light emitting units 41 are lamps that focus light on the protrusions 15b in this embodiment, the present invention is not limited thereto and the light emitting units 41 may be laser devices emitting laser light with high directivity. In general, light emitted by the light emitting units 41 may be electromagnetic radiation including visible light and ultraviolet light. Furthermore, light emitted by the light emitting units 41 is not limited to one kind of light, but it may be a combination of several kinds of light, e.g., a combination of a laser light and a ultraviolet light.

There might be only one light emitting unit 41. Alternatively, a plurality of light emitting units 41 might be formed corresponding to the plurality of protrusions 15b (e.g., three light emitting units 41 in this embodiment). If only one light emitting units 41 is formed, the transfer device 15 is moved to sequentially stop the plurality of protrusions 15b at a focal point of the light emitting unit 41. If a plurality (e.g., three) of light emitting units 41 are formed, the focal points might be set in advance at the position of protrusions 15b of the time when the transfer device 15 stops at a waiting position.

Although the transmissive window 14a is disposed right above the protrusions 15b in the above embodiment, the present invention is not limited thereto and it may be formed in an arbitrary position. For example, the see-through window in the substrate processing apparatus of the prior art may be used as a transmissive window 14a. In this case, light may be obliquely emitted to the protrusions 15b by the light emitting units 41.

Preferably, the light emitting units 41 may be disposed outside the transfer chamber 14. If the light emitting units 41 are disposed inside the transfer chamber 14, deposits separated from the protrusions 15b may be adhered to the light emitting units 41.

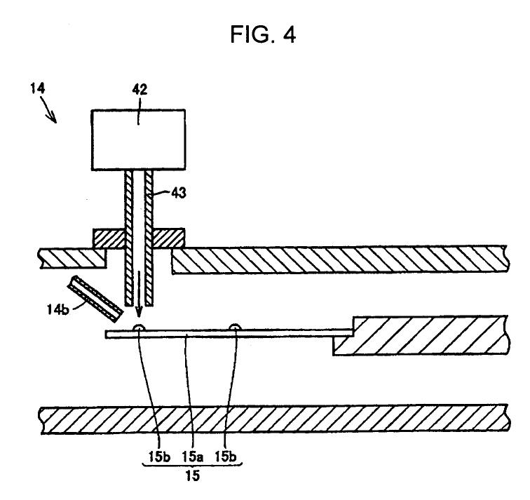

Another foreign substance removing unit will now be explained with reference to FIG. 4. The same elements in FIG. 4 as those in FIG. 3 are denoted by the same reference numerals, and thus a detailed explanation thereof will not be given. In this embodiment, the foreign substance removing unit includes an ozone gas generating unit 42 for generating ozone gas and the nozzle 43 for selectively injecting the generated ozone gas toward the protrusions 15b. The foreign substance removing unit constructed as described above can remove deposits accumulated on the protrusions 15b.

Preferably, the ozone gas injected from the nozzle 43 may be excited by plasma to improve the efficiency in removing deposits. The efficiency in removing the deposits can be further improved by combining the foreign substance removing unit of FIG. 3 and the foreign substance removing unit of FIG. 4.

Although the ozone gas is selectively injected toward the protrusions 15b in the above embodiment, the present invention is not limited thereto and the ozone gas may be filled in the atmosphere of the transfer chamber 14. In this case, there is no particular limitation in how the ozone gas is generated. For example, the ozone gas may be generated by introducing a gas such as oxygen into the transfer chamber 14 and irradiating ultraviolet light to the gas, or may be generated by using an ozonizer disposed outside the transfer chamber 14.

Each of the foreign substance removing units of the above embodiments can effectively remove a CFx compound. But it is not limited to remove CFx compounds. Of course, it is possible to remove other organic compounds as well.

As described above, since foreign substances are removed in the transfer chamber 14 without using an exclusive cleaning unit, the area occupied by the substrate processing apparatus is not increased. Furthermore, since the cleaning is performed in the transfer chamber that is in a depressurized state, a harmful gas produced during the cleaning process can be effectively prevented from leaking. Moreover, since the foreign substances are removed in the transfer chamber that is kept in a depressurized state, the throughput of the substrate processing apparatus can be prevented from being reduced.

While the present invention has been particularly shown and described with reference to exemplary embodiments thereof, the present invention is not limited to the shown and described embodiments. It will be understood by one of ordinary skill in the art that various changes or modifications may be made to the shown and described embodiments in the same or equivalent scope of the present invention.

What is claimed is:

1. A substrate processing apparatus comprising:
at least one processing chamber in which a substrate is processed;
a transfer chamber disposed adjacent to the at least one processing chamber;
a depressurizing unit for depressurizing an inside of the transfer chamber;
a transfer device for carrying the substrate between the transfer chamber and the at least one processing chamber; and
a foreign substance removing unit for removing foreign substances adhered to the transfer device in the transfer chamber.

2. The substrate processing apparatus of claim 1, wherein the foreign substance removing unit comprises a light emitting unit for emitting light toward the transfer device.

3. The substrate processing apparatus of claim 2, wherein the foreign substance removing unit removes the foreign substances in the transfer chamber by using ozone gas.

4. The substrate processing apparatus of claim 3, wherein the foreign substance removing unit comprises an ozone gas supply unit for supplying ozone gas into the transfer chamber.

5. The substrate processing apparatus of claim 3, wherein the foreign substance removing unit comprises an ozone gas injecting unit for injecting ozone gas toward the transfer device.

6. The substrate processing apparatus of claim 1, wherein the foreign substance removing unit comprises an ozone gas injecting unit for injecting ozone gas toward the transfer device.

7. The substrate processing apparatus of claim 2, wherein a surface of the transfer device is covered with a titanium oxide layer.

8. The substrate processing apparatus of claim 2, wherein the transfer chamber has a transmissive window through which light is transmitted, and the light emitting unit emits light toward the transfer device through the transmissive window from the outside of the transfer chamber.

9. The substrate processing apparatus of claim 1, wherein the transfer device has a plurality of protrusions formed on a top surface thereof and supporting the substrate, and the foreign substance removing unit selectively removes foreign substances adhered to the plurality of protrusions.

10. The substrate processing apparatus of claim 1, wherein the transfer chamber comprises a suction device for forcibly discharging the foreign substances separated from the transfer device.

11. A substrate processing apparatus comprising:
at least one processing chamber in which a substrate is processed;
a transfer chamber disposed adjacent to the at least one processing chamber;
a depressurizing unit for depressurizing an inside of the transfer chamber;
a load lock chamber disposed adjacent to the transfer chamber;
a first transfer device disposed in the transfer chamber and carrying the substrate to the processing chamber and the load lock chamber under a depressurized atmosphere;
a loader unit disposed adjacent to the load lock chamber and comprising a cassette for receiving the substrate and a second transfer device for carrying the substrate between the load lock chamber and the cassette; and
a foreign substance removing unit for removing foreign substances adhered to the first transfer device in the transfer chamber.
